(19) United States
(12) Patent Application Publication
(10) Pub. No.: US 2026/0006855 A1
(43) Pub. Date: Jan. 1, 2026

(54) FLASH MEMORY AND METHOD FOR MAKING THE SAME

(71) Applicant: Shanghai Huali Microelectronics Corporation, Shanghai (CN)

(72) Inventors: Wenyu GUO, Shanghai (CN); Shipu LI, Shanghai (CN)

(21) Appl. No.: 18/885,272

(22) Filed: Sep. 13, 2024

(30) Foreign Application Priority Data
Jun. 28, 2024 (CN) 202410865166.3

(51) Int. Cl. H01L 29/792; H01L 29/66; H10B 43/30

(52) U.S. Cl. CPC H10D 30/69; H10B 43/30; H10D 30/0413

(57) ABSTRACT

The present application discloses a flash memory, wherein a gate dielectric layer of a storage transistor comprises a tunneling dielectric layer, a storage dielectric layer, and a barrier dielectric layer stacked in sequence. The storage dielectric layer includes a first silicon nitride layer, a second interface layer, and a third silicon nitride layer stacked in sequence. The material for the second interface layer is silicon oxynitride. With the storage transistor in a programming state, programming electrons are stored in the defect of the first silicon nitride layer and the defect of the third silicon nitride layer, and the outflow of the programming electrons out of the storage dielectric layer is reduced by means of the feature that the width of band gap of silicon oxynitride is greater than that of silicon nitride. The present application also discloses a method of making a flash memory.

### CROSS-REFERENCES TO RELATED APPLICATIONS

This application claims priority to Chinese patent application No. CN202410865166.3, filed on Jun. 28, 2024, the disclosure of which is incorporated herein by reference in its entirety.

### TECHNICAL FIELD

The present application relates to the field of semiconductor integrated circuit manufacture, and in particular to a flash memory. The present application also relates to a method of making a flash memory.

### BACKGROUND

An oxide-nitride-oxide (ONO) structure is significant to enhance the stability of a silicon-oxide-nitride-oxide-silicon (SONOS) flash device, and is of great significance to improve an ONO structure and precisely control the reliability of an SONOS Flash memory.

In existing processes, ONO is generally used as a floating gate electrode. Three layers of films are grown on a whole wafer by an ONO machine. Then, a top oxide in the ONO structure is removed by wet cleaning, and then an ONO area is exposed to remove ONO films in other areas, that is, all ONO films except for the flash memory cell area with the ONO structure are removed. Finally, a top oxide is grown in the ONO structure by the in situ steam generation (ISSG) process to finally form an ONO sandwich structure.

However, due to an enhancement of a short channel effect, an SONOS memory cell may have performance loss at gate lengths below 50 nm. A reduced memory cell facilitates the design of dense memories, but a relatively small gate length reduces the erase count and the stability of SONOS Flash memories.

### BRIEF SUMMARY

According to some embodiments in this application, a gate dielectric layer of a storage transistor of a flash memory provided by the present application comprises a tunneling dielectric layer, a storage dielectric layer, and a barrier dielectric layer stacked in sequence.

The storage dielectric layer includes a first silicon nitride layer, a second interface layer, and a third silicon nitride layer stacked in sequence.

The first silicon nitride layer and the third silicon nitride layer have defects for storing programming electrons.

The material for the second interface layer is silicon oxynitride.

With the storage transistor in a programming state, programming electrons are stored in the defect of the first silicon nitride layer and the defect of the third silicon nitride layer, and the second interface layer is used to reduce the outflow of the programming electrons out of the storage dielectric layer by means of the feature that the width of band gap of silicon oxynitride is greater than that of silicon nitride.

In some examples, the second interface layer is formed by treating the top surface region of the first silicon nitride layer with oxygen and nitrogen.

In some examples, the material of the tunneling dielectric layer comprises an oxide layer.

In some examples, the material of the barrier dielectric layer comprises an oxide layer.

In some examples, the storage transistor further comprises a gate conductive material layer on a top surface of the barrier dielectric layer.

In some examples, the material of the gate conductive material layer comprises polysilicon.

In some examples, the initial memory window of the storage transistor is regulated by a ratio of contents of oxygen and nitrogen in the second interface layer, and the initial memory window of the storage transistor is increased by increasing an oxygen content.

To solve the above technical problem, the present application provides a method of making a flash memory, wherein a gate dielectric layer of a storage transistor comprises a tunneling dielectric layer, a storage dielectric layer, and a barrier dielectric layer stacked in sequence, and the step of forming the gate dielectric layer of the storage transistor comprises:
step 1. forming the tunneling dielectric layer on a surface of a semiconductor substrate;
step 2. forming the storage dielectric layer, comprising the following sub-steps:
step 21. depositing a first silicon nitride layer;
step 22. forming a second interface layer consisting of silicon oxynitride on the surface of the first silicon nitride layer; and
step 23. forming a third silicon nitride layer on the surface of the second interface layer;
wherein the third silicon nitride layer has a defect for storing programming electrons; and
With the storage transistor in a programming state, programming electrons are stored in the defect of the first silicon nitride layer and the defect of the third silicon nitride layer, and the second interface layer is used to reduce the outflow of the programming electrons out of the storage dielectric layer by means of the feature that the width of band gap of silicon oxynitride is greater than that of silicon nitride; and
step 3. forming the barrier dielectric layer on the surface of the storage dielectric layer.

In some examples, in step 22, the second interface layer is formed by treating the top surface region of the first silicon nitride layer with oxygen and nitrogen.

In some examples, in step 21, the first silicon nitride layer is formed by deposition using a CVD process; and

in step 23, the second silicon nitride layer is formed by deposition using a CVD process.

In some examples, step 22 is to form the second interface layer by in-situ feeding of oxygen and nitrogen after stopping the CVD process deposition for the first silicon nitride layer after completion of step 21.

In some examples, the material of the tunneling dielectric layer comprises an oxide layer.

In some examples, the material of the barrier dielectric layer comprises an oxide layer.

In some examples, the method further comprises, after the gate dielectric layer of the storage transistor is formed:

step 4. performing pattern etching on the gate dielectric layer of the storage transistor to remove the gate dielectric layer of the storage transistor outside the formation region of the storage transistor and retain the gate dielectric layer of the storage transistor in the formation region of the storage transistor.

In some examples, it further comprises: step 5. forming a gate conductive material layer, wherein the gate conductive material layer is formed on a top surface of the barrier dielectric layer in the formation region of the storage transistor.

In some examples, the material of the gate conductive material layer comprises polysilicon.

In some examples, the initial memory window of the storage transistor is regulated by a ratio of contents of oxygen and nitrogen in the second interface layer, and the initial memory window of the storage transistor is increased by increasing an oxygen content; and in step 22, the ratio of the contents of oxygen and nitrogen in the second interface layer is adjusted by adjusting a ratio of flow rates of oxygen and nitrogen.

In the present application, a process structure of the storage dielectric layer is specially set, wherein the second interface layer is inserted between the first silicon nitride layer and the third silicon nitride layer, and the material of the second interface layer is silicon oxynitride. Thus, the present application reduces the leakage of the programming electrons stored in the storage dielectric layer, i.e., the leakage of the programming electrons stored in the defect of the first silicon nitride layer and the defect of the third silicon nitride layer, by means of the feature of a relatively wide width of band gap of silicon oxynitride, thereby improving the reliability of a storage transistor device and enabling an increased erase count and stability of a storage transistor.

The present application enables the second interface layer which can be realized only by treating the first silicon nitride layer with oxygen and nitrogen, and thus, the application is easy to realize due to a simple process and is of low cost.

The present application can also adjust the initial memory window of the storage transistor by the ratio of the contents of oxygen and nitrogen for the second interface layer, thereby further facilitating an adjustment of a device performance.

### BRIEF DESCRIPTION OF THE DRAWINGS

The present application is described in further detail below in connection with figures and specific embodiments:

FIG. 1 is a schematic diagram of a structure of a storage transistor of a flash memory of an embodiment of the present application;

FIGS. 2A-FIG. 2F are schematic diagrams of the structure of the storage transistor in each step of the method of making a flash memory of an embodiment of the present application;

FIG. 3A is a schematic diagram of a structure of a device inside and outside a formation region of a storage transistor before pattern etching in step 4 of the method of making a flash memory of an embodiment of the present application; and

FIG. 3B is a schematic diagram of a structure of a device inside and outside a formation region of a storage transistor after pattern etching in step 4 of the method of making a flash memory of an embodiment of the present application.

### DETAILED DESCRIPTION OF THE DISCLOSURE

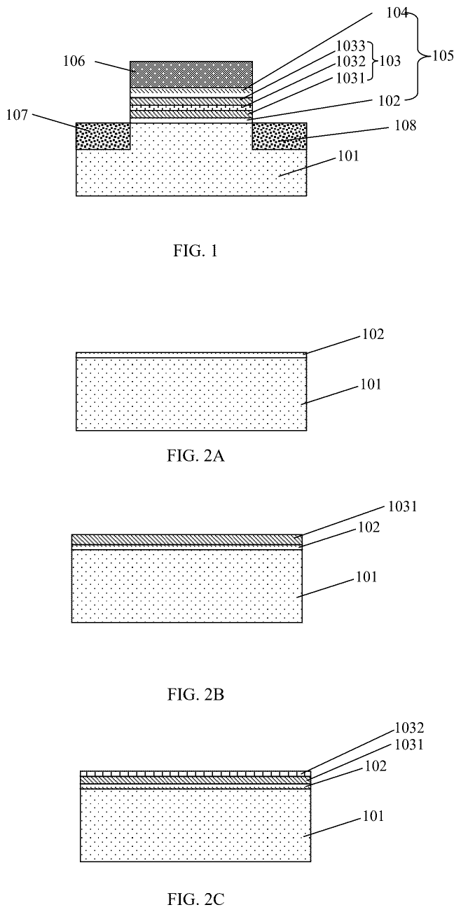

Referring to FIG. 1, it is a schematic diagram of a structure of a storage transistor of a flash memory of an embodiment of the present application. In an embodiment of the present application, a gate dielectric layer 105 of a storage transistor of a flash memory comprises a tunnelling dielectric layer 102, a storage dielectric layer 103, and a barrier dielectric layer 104 stacked in sequence.

The storage dielectric layer 103 includes a first silicon nitride layer 1031, a second interface layer 1032, and a third silicon nitride layer 1033 stacked in sequence.

The first silicon nitride layer 1031 and the third silicon nitride layer 1033 have defects for storing programming electrons.

The material for the second interface layer 1032 is silicon oxynitride.

In the embodiment of the present application, the silicon nitride material of the first silicon nitride layer 1031 and the third silicon nitride layer 1033 is represented as Si₃N₄, and the silicon oxynitride material of the second interface layer 1032 is represented as SiOₓN_{y}, where x and y are corresponding numbers, x is the number of oxygen atoms in a silicon oxynitride molecule, and y is the number of N atoms in a silicon oxynitride molecule.

In an embodiment of the application, the second interface layer 1032 is formed by treating the top surface region of the first silicon nitride layer 1031 with oxygen and nitrogen. The second interface layer 1032 has a good interface structure by forming the second interface layer 1032 by treating the top surface region of the first silicon nitride layer 1031 with oxygen and nitrogen.

In an embodiment of the application, the initial memory window of the storage transistor is regulated by a ratio of contents of oxygen and nitrogen in the second interface layer 1302, and the initial memory window of the storage transistor is increased by increasing an oxygen content.

With the storage transistor in a programming state, programming electrons are stored in the defect of the first silicon nitride layer 1031 and the defect of the third silicon nitride layer 1033, and the second interface layer 1302 is used to reduce the outflow of the programming electrons out of the storage dielectric layer by means of the feature that the width of band gap of silicon oxynitride is greater than that of silicon nitride. In the present application, programming electrons mean the electrons that are injected into, by programing, and stored in the storage dielectric layer 103.

In an embodiment of the present application, the material of the tunneling dielectric layer 102 comprises an oxide layer.

The material of the barrier dielectric layer 104 comprises an oxide layer.

The storage transistor further comprises a gate conductive material layer 106 on a top surface of the barrier dielectric layer 104. The material of the gate conductive material layer 106 comprises polysilicon.

The tunneling dielectric layer 102 is formed on a surface of a semiconductor substrate 101. The material of the semiconductor substrate 101 includes a silicon substrate.

The gate structure of the storage transistor is formed by stacking the gate dielectric layer 105 and the gate conductive material layer 106.

A source region 107 and a drain region 108 are formed in the semiconductor substrates 101 at both sides of the gate structure of the storage transistor. The surface region of the semiconductor substrate 101 covered by the gate structure of the storage transistor is a channel region.

The silicon substrate, the tunneling dielectric layer 102 consisting of the oxide layer, the first silicon nitride layer 1031, the third silicon nitride layer 1033, the barrier dielectric layer 104, and the gate conductive material layer 106 consisting of polysilicon can be represented as Silicon-Oxide-Nitride-Nitride-Oxide-Silicon, abbreviated as SONNOS, and the flash memory is an SONNOS flash memory.

In the embodiment of the present application, a process structure of the storage dielectric layer 103 is specially set, wherein the second interface layer 1032 is inserted between the first silicon nitride layer 1031 and the third silicon nitride layer 1033, and the material of the second interface layer 1032 is silicon oxynitride. Thus, the present application reduces the leakage of the programming electrons stored in the storage dielectric layer 103, i.e., the leakage of the programming electrons stored in the defect of the first silicon nitride layer 1031 and the defect of the third silicon nitride layer 1033, by means of the feature of a relatively wide width of band gap of silicon oxynitride, thereby improving the reliability of a storage transistor device and enabling an increased erase count and stability of a storage transistor.

The embodiment of the present application enables the second interface layer 1032 which can be realized only by treating the first silicon nitride layer 1031 with oxygen and nitrogen, and thus, the application is easy to realize due to a simple process and is of low cost.

The embodiment of the present application can also adjust the initial memory window of the storage transistor by the ratio of the contents of oxygen and nitrogen for the second interface layer 1032, thereby further facilitating an adjustment of a device performance.

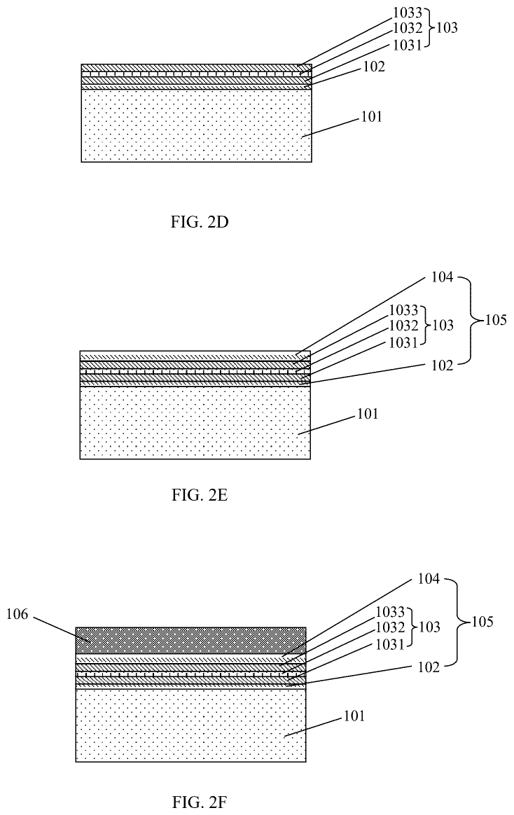

Referring to FIGS. 2A to 2F, they are schematic diagrams of the structure of the storage transistor in each step of the method of making a flash memory of an embodiment of the present application; and in the method, the gate dielectric layer 105 of the storage transistor comprises a tunneling dielectric layer 102, a storage dielectric layer 103, and a barrier dielectric layer 104 stacked in sequence, and the step of forming the gate dielectric layer 105 of the storage transistor comprises:

step 1. forming the tunneling dielectric layer 102 on the surface of semiconductor substrate 101, referring to FIG. 2A.

In the method of the embodiment of the present application, the semiconductor substrate 101 comprises a silicon substrate.

The material of the tunneling dielectric layer 102 comprises an oxide layer.

In some embodiment methods, the semiconductor substrate 101 is oxidized by using a thermal oxidation process to form the tunneling dielectric layer 102.

The method includes step 2. forming the storage dielectric layer 103, comprising the following sub-steps:

step 21. depositing a first silicon nitride layer 1031, referring to FIG. 2B.

In the method of the embodiment of the present application, the first silicon nitride layer 1031 is formed by deposition using a CVD process.

Step 2 also includes step 22. forming a second interface layer 1032 consisting of silicon oxynitride on the surface of the first silicon nitride layer 1031, referring to FIG. 2C.

In the method of the embodiment of the present application, the second interface layer 1032 is formed by treating the top surface region of the first silicon nitride layer 1031 with oxygen and nitrogen. More preferably, step 22 is to form the second interface layer 1032 by in-situ feeding of oxygen and nitrogen after stopping the CVD process deposition for the first silicon nitride layer 1031 after completion of step 21. The in-situ feeding of oxygen and nitrogen means that oxygen and nitrogen are fed into the same CVD process chamber without moving of the semiconductor substrate 101.

In the method of the embodiment of the present application, the initial memory window of the storage transistor is regulated by a ratio of contents of oxygen and nitrogen in the second interface layer 1032, and the initial memory window of the storage transistor is increased by increasing an oxygen content, and the ratio of the contents of oxygen and nitrogen in the second interface layer 1032 is adjusted by adjusting a ratio of flow rates of oxygen and nitrogen in step 22.

Step 2 further includes step 23. forming a third silicon nitride layer 1033 on the surface of the second interface layer 1032, referring to FIG. 2D.

The third silicon nitride layer 1033 has a defect for storing programming electrons.

With the storage transistor in a programming state, programming electrons are stored in the defect of the first silicon nitride layer 1031 and the defect of the third silicon nitride layer 1033, and the second interface layer 1032 is used to reduce the outflow of the programming electrons out of the storage dielectric layer 103 by means of the feature that the width of band gap of silicon oxynitride is greater than that of silicon nitride.

In the method of the embodiment of the present application, the second silicon nitride layer is formed by deposition using a CVD process.

The method further includes step 3. forming the barrier dielectric layer 104 on the surface of the storage dielectric layer 103, referring to FIG. 2E.

In the method of the embodiment of the present application, the material of the barrier dielectric layer 104 comprises an oxide layer, and the barrier dielectric layer 104 is formed by a thermal deposition process.

The method further comprises, after the gate dielectric layer 105 of the storage transistor is formed:
step 4. performing pattern etching on the gate dielectric layer 105 of the storage transistor to remove the gate dielectric layer 105 of the storage transistor outside the formation region of the storage transistor and retain the gate dielectric layer 105 of the storage transistor in the formation region of the storage transistor.

FIG. 2E only shows a schematic view of the structure in the formation region of the storage transistor, and the schematic view of the structure before and after the pattern etching of step 4 is the same. The change in a device structure before and after the pattern etching is further described below.

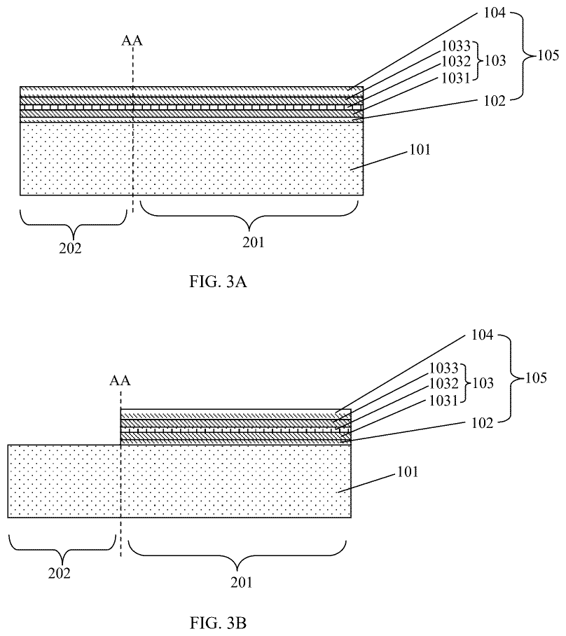

Referring to FIG. 3A, it is a schematic diagram of a structure of a device inside and outside a formation region of a storage transistor before pattern etching in step 4 of the method of making a flash memory of an embodiment of the present application. In FIG. 3A, the region shown in a curly bracket 201 to the right of dashed line AA is the formation region of the storage transistor, and the region shown in a curly bracket 202 to the left of dashed line AA is the region outside the formation region of the storage transistor. The region shown in the curly bracket 202 includes: the formation region of the selection transistor and the formation region of the logic device outside the flash memory.

Referring to FIG. 3B, since the gate dielectric layer 105 of the storage transistor only needs to be formed in the formation region of the storage transistor, it is necessary to remove the gate dielectric layer 105 outside the formation region of the storage transistor by pattern etching. Outside the formation area of the storage transistor, a gate dielectric layer of the selector transistor or a gate dielectric layer of the logic device is formed as needed.

After that, the method includes:
step 5. forming a gate conductive material layer 106, wherein the gate conductive material layer 106 is formed on a top surface of the barrier dielectric layer 104 in the formation region of the storage transistor, referring to FIG. 2F.

The material of the gate conductive material layer 106 comprises polysilicon.

Step 5 comprises the following sub-steps.

The gate conductive material layer 106 is deposited, referring to FIG. 2F.

A formation region of a gate structure of the storage transistor is photolithographically defined, referring to FIG. 1.

Then, the gate conductive material layer 106, and the gate dielectric layer 105 of the storage transistor are etched to form the gate structure of the storage transistor.

Then, source-drain injection is performed to form a source region 107 and a drain region 108 in the semiconductor substrate 101 at both sides of the gate structure of the storage transistor.

In the method of the embodiment of the present application, the gate dielectric layer of the storage transistor is dual-stack Si3N4 with a layer of SiOₓN_{y} grown therein, thereby forming a novel SONNOS storage transistor; and SiOₓN_{y} can prevent electron outflow, thereby improving the reliability of the SONNOS memory. As shown by experimental data, for SONNOS, an initial memory window is about 3.9 V, and after 10⁴ programming and erasing (P/E) cycles, the memory window is reduced by only 0.4 V. It is indicated by extrapolation that the SONNOS device of the embodiment of the present application retains 42% of an original memory window after 10 years of use.

The application is described in detail above by specific embodiments without limitation to the application. Without departing from the principle of the present application, modifications and improvements may be made by those skilled in the art, which shall also be within the scope of protection of the present application.

What is claimed is:

1. A flash memory, wherein a gate dielectric layer of a storage transistor comprises a tunneling dielectric layer, a storage dielectric layer, and a barrier dielectric layer stacked in sequence;
the storage dielectric layer includes a first silicon nitride layer, a second interface layer, and a third silicon nitride layer stacked in sequence;
the first silicon nitride layer and the third silicon nitride layer have defects for storing programming electrons;
the material for the second interface layer is silicon oxynitride; and
with the storage transistor in a programming state, programming electrons are stored in the defect of the first silicon nitride layer and the defect of the third silicon nitride layer, and the second interface layer is used to reduce the outflow of the programming electrons out of the storage dielectric layer by means of the feature that the width of band gap of silicon oxynitride is greater than that of silicon nitride.

2. The flash memory according to claim 1, wherein the second interface layer is formed by treating the top surface region of the first silicon nitride layer with oxygen and nitrogen.

3. The flash memory according to claim 1, wherein the material of the tunneling dielectric layer comprises an oxide layer.

4. The flash memory according to claim 1, wherein the material of the barrier dielectric layer comprises an oxide layer.

5. The flash memory according to claim 1, wherein the storage transistor further comprises a gate conductive material layer on a top surface of the barrier dielectric layer.

6. The flash memory according to claim 5, wherein the material of the gate conductive material layer comprises polysilicon.

7. The flash memory according to claim 2, wherein the initial memory window of the storage transistor is regulated by a ratio of contents of oxygen and nitrogen in the second interface layer, and the initial memory window of the storage transistor is increased by increasing an oxygen content.

8. A method of making a flash memory, wherein a gate dielectric layer of a storage transistor comprises a tunneling dielectric layer, a storage dielectric layer, and a barrier dielectric layer stacked in sequence, and the step of forming the gate dielectric layer of the storage transistor comprises:
step 1. forming the tunneling dielectric layer on a surface of a semiconductor substrate;
step 2. forming the storage dielectric layer, comprising the following sub-steps:
step 21. depositing a first silicon nitride layer;
step 22. forming a second interface layer consisting of silicon oxynitride on the surface of the first silicon nitride layer; and
step 23. forming a third silicon nitride layer on the surface of the second interface layer;
wherein the third silicon nitride layer has a defect for storing programming electrons; and
with the storage transistor in a programming state, programming electrons are stored in the defect of the first silicon nitride layer and the defect of the third silicon nitride layer, and the second interface layer is used to reduce the outflow of the programming electrons out of the storage dielectric layer by means of the feature that the width of band gap of silicon oxynitride is greater than that of silicon nitride; and
step 3. forming the barrier dielectric layer on the surface of the storage dielectric layer.

9. The method of making a flash memory according to claim 8, wherein in step 22, the second interface layer is formed by treating the top surface region of the first silicon nitride layer with oxygen and nitrogen.

10. The method of making a flash memory according to claim 9, wherein in step 21, the first silicon nitride layer is formed by deposition using a CVD process; and
in step 23, the second silicon nitride layer is formed by deposition using a CVD process.

11. The method of making a flash memory according to claim 10, wherein step 22 is to form the second interface layer by in-situ feeding of oxygen and nitrogen after stopping the CVD process deposition for the first silicon nitride layer after completion of step 21.

12. The method of making a flash memory according to claim 8, wherein the material of the tunneling dielectric layer comprises an oxide layer.

13. The method of making a flash memory according to claim 8, wherein the material of the barrier dielectric layer comprises an oxide layer.

14. The method of making a flash memory according to claim 8, wherein it further comprises, after the gate dielectric layer of the storage transistor is formed:
step 4. performing pattern etching on the gate dielectric layer of the storage transistor to remove the gate dielectric layer of the storage transistor outside the formation region of the storage transistor and retain the gate dielectric layer of the storage transistor in the formation region of the storage transistor.

15. A method of making a flash memory according to claim 14, further comprising:
step 5. forming a gate conductive material layer, wherein the gate conductive material layer is formed on a top surface of the barrier dielectric layer in the formation region of the storage transistor.

16. The method of making a flash memory according to claim 15, wherein the material of the gate conductive material layer comprises polysilicon.

17. The method of making a flash memory according to claim 9, wherein the initial memory window of the storage transistor is regulated by a ratio of contents of oxygen and nitrogen in the second interface layer, and the initial memory window of the storage transistor is increased by increasing an oxygen content; and in step 22, the ratio of the contents of oxygen and nitrogen in the second interface layer is adjusted by adjusting a ratio of flow rates of oxygen and nitrogen.
